(19) United States
(12) Patent Application Publication
(10) Pub. No.: US 2025/0351745 A1
(43) Pub. Date: Nov. 13, 2025

(54) METHOD OF FORMING RESISTIVE RANDOM ACCESS MEMORY (RRAM) CELLS

(71) Applicant: Silicon Storage Technology, Inc., San Jose, CA (US)

(72) Inventors: Feng Zhou, Fremont, CA (US); Xian Liu, Sunnyvale, CA (US); Yi Song, San Jose, CA (US); Hieu Van Tran, San Jose, CA (US); Nhan Do, Saratoga, CA (US)

(21) Appl. No.: 18/803,363

(22) Filed: Aug. 13, 2024

Related U.S. Application Data
(60) Provisional application No. 63/644,433, filed on May 8, 2024.

(51) Int. Cl. H10N 70/00; H10B 63/00; H10N 70/20

(52) U.S. Cl. CPC H10N 70/063; H10B 63/30; H10N 70/24; H10N 70/8265

(57) ABSTRACT

A method of forming a semiconductor device, comprising forming insulation material over a semiconductor substrate, forming a conductive contact through the insulation material, forming a lower electrode layer over the insulation material and electrically connected with the conductive contact, forming a resistive switching dielectric material (RSDM) layer directly on the lower electrode layer, forming an upper electrode layer directly on the RSDM layer, selectively removing portions of the upper electrode layer to form a block of the upper electrode layer, selectively removing portions of the RSDM layer to form a block of the RSDM layer disposed under the block of the upper electrode layer, forming insulation spacers on the lower electrode layer and extending along sidewalls of the block of the upper electrode layer and the block of the RSDM layer, and selectively removing portions of the lower electrode layer to form a block of the lower electrode layer.

### RELATED APPLICATIONS

This application claims the benefit of U.S. Provisional Application No. 63/644,433, filed May 8, 2024, and which is incorporated herein by reference.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive switching dielectric material layer sandwiched between two conductive electrodes. The resistive switching dielectric material is normally insulating. However, by applying the proper voltage across the resistive switching dielectric material layer, a conduction path (typically referred to as a filament) can be formed through the resistive switching dielectric material layer resulting in a lower resistance across the RRAM cell. Once the filament is formed, it can be “reset” (i.e., broken or ruptured, resulting in a high resistance across the RRAM cell) and set (i.e., re-formed, again resulting in a lower resistance across the RRAM cell), by applying the appropriate voltages across the resistive switching dielectric material layer. The low and high resistance states can be utilized to indicate a digital state of “1” or “0” depending upon the resistance state, and thereby provide a reprogrammable non-volatile memory cell that can store a bit of information.

FIG. 1 shows a conventional configuration of an RRAM memory cell 1. The memory cell 1 includes a resistive switching dielectric material layer 2 sandwiched between two conductive material layers that form an upper electrode 3 and a lower electrode 4.

FIGS. 2A-2D show the switching mechanism of the resistive switching dielectric material layer 2. Specifically, FIG. 2A shows the resistive switching dielectric material layer 2 in its initial state after fabrication, where the layer 2 exhibits a relatively high resistance. FIG. 2B shows the formation of a conductive filament 7 through the layer 2 by applying the appropriate voltage across the layer 2. The filament 7 is a conductive path through the layer 2, such that the layer exhibits a relatively low resistance across it (because of the relatively high conductivity of the filament 7). FIG. 2C shows the formation of a rupture 8 in filament 7 caused by the application of a “reset” voltage across the layer 2. The area of the rupture 8 has a relatively high resistance, so that layer 2 exhibits a relatively high resistance across it. FIG. 2D shows the restoration of the filament 7 in the area of the rupture 8 caused by the application of a “set” voltage across layer 2. The restored filament 7 means the layer 2 exhibits a relatively low resistance across it. The relatively low resistance of layer 2 in the “formed” or “set” states of FIGS. 2B and 2D respectively can represent a digital state (e.g. a “1”), and the relatively high resistance of layer 2 in the “reset” state of FIG. 2C can represent a different digital state (e.g. a “0”). The reset voltage (which breaks the filament) can have a polarity opposite that of the filament formation and the set voltages, but it can also have the same polarity. The RRAM cell 1 can repeatedly be “reset” and “set,” so it forms a reprogrammable nonvolatile memory cell.

There is a need for an improved methodology for fabricating RRAM cells that simplifies manufacturing and increases yield and performance.

### BRIEF SUMMARY OF THE INVENTION

The aforementioned problems and needs are addressed by a method of forming a semiconductor device, comprising forming insulation material over a semiconductor substrate, forming a first contact hole extending through the insulation material, forming a first conductive contact in the first contact hole, forming a lower electrode layer over the insulation material and electrically connected with the first conductive contact, forming a resistive switching dielectric material layer directly on the lower electrode layer, forming an upper electrode layer directly on the resistive switching dielectric material layer, selectively removing portions of the upper electrode layer to form a block of the upper electrode layer, selectively removing portions of the resistive switching dielectric material layer to form a block of the resistive switching dielectric material layer disposed under the block of the upper electrode layer, forming insulation spacers on the lower electrode layer and extending along sidewalls of the block of the upper electrode layer and the block of the resistive switching dielectric material layer, and selectively removing portions of the lower electrode layer to form a block of the lower electrode layer, wherein the block of the lower electrode layer is disposed under the insulation spacers and the block of the resistive switching dielectric material layer and the block of the upper electrode layer.

Other objects and features of the present disclosure will become apparent by a review of the specification, claims and appended figures.

### BRIEF DESCRIPTION OF THE DRAWINGS

FIG. 1 is a side cross sectional view of a conventional RRAM memory cell.

FIG. 2A is a side cross sectional view of a conventional RRAM memory cell in its initial state.

FIG. 2B is a side cross sectional view of a conventional RRAM memory cell illustrating the formation of a conductive filament.

FIG. 2C is a side cross sectional view of a conventional RRAM memory cell illustrating the formation of a rupture in the conductive filament.

FIG. 2D is a side cross sectional view of a conventional RRAM memory cell illustrating the restoration of the conductive filament in the area of the rupture.

FIGS. 3A-3H are side cross sectional views illustrating the formation of a RRAM memory cell.

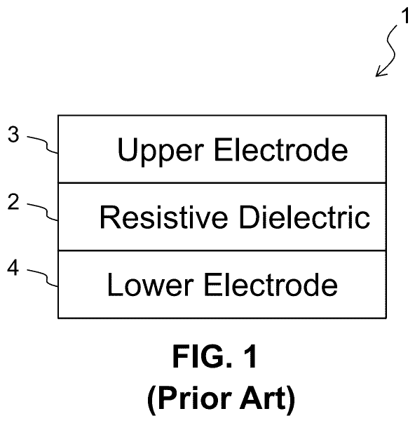

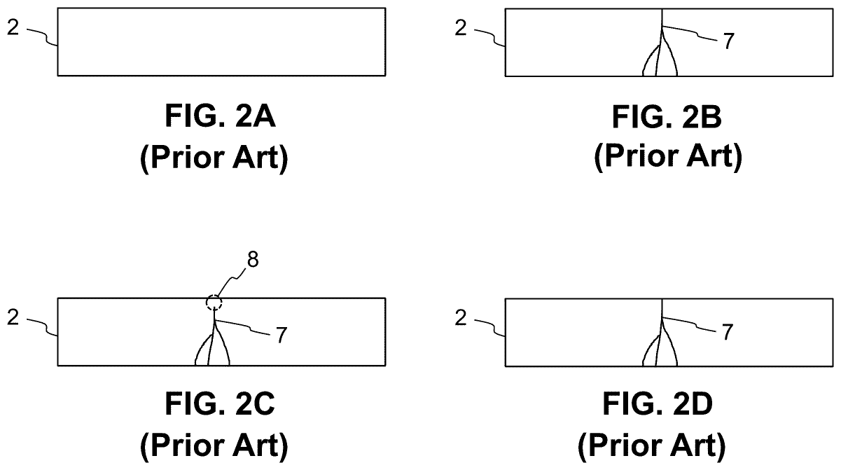

### DETAILED DESCRIPTION OF THE INVENTION

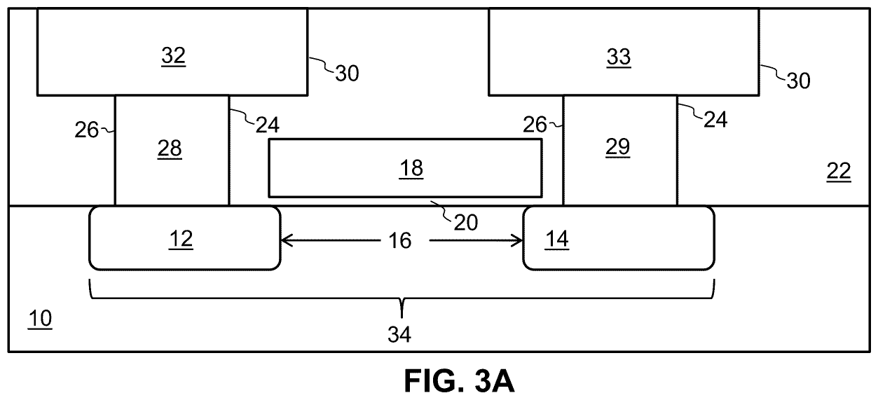

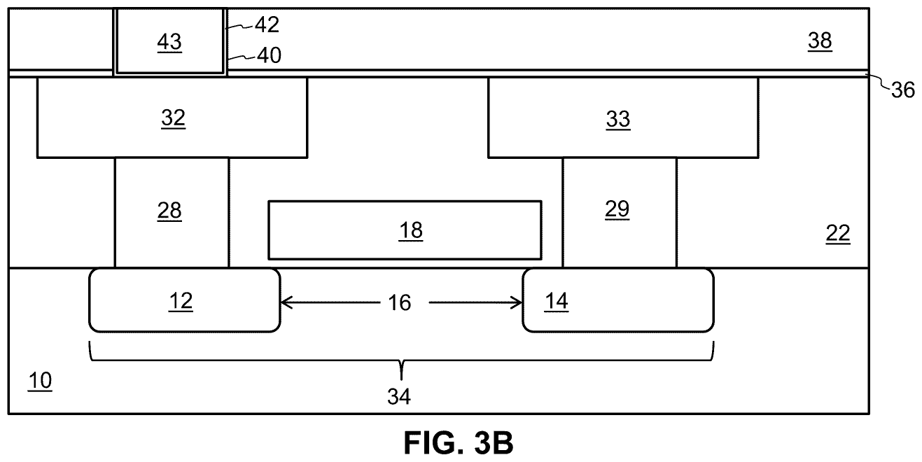

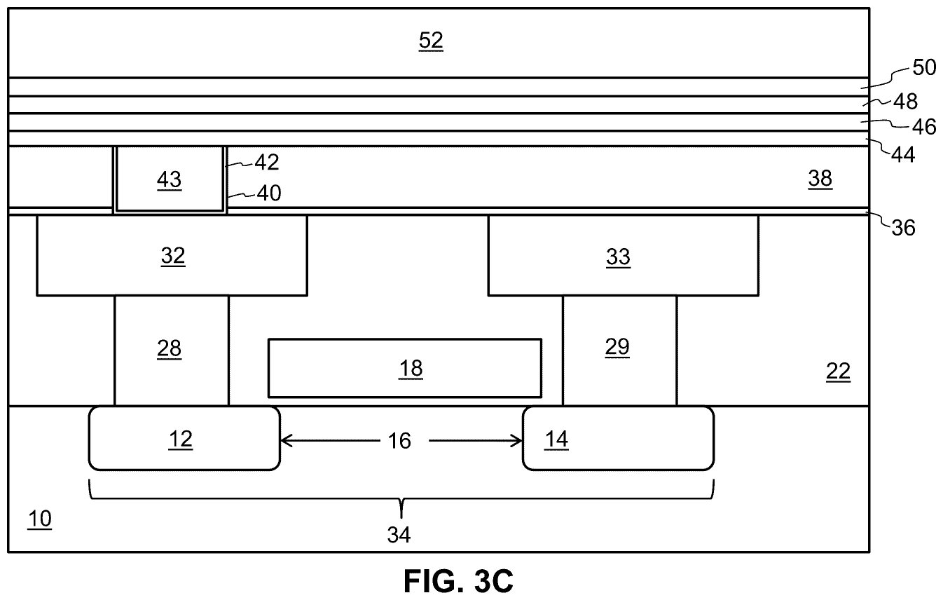

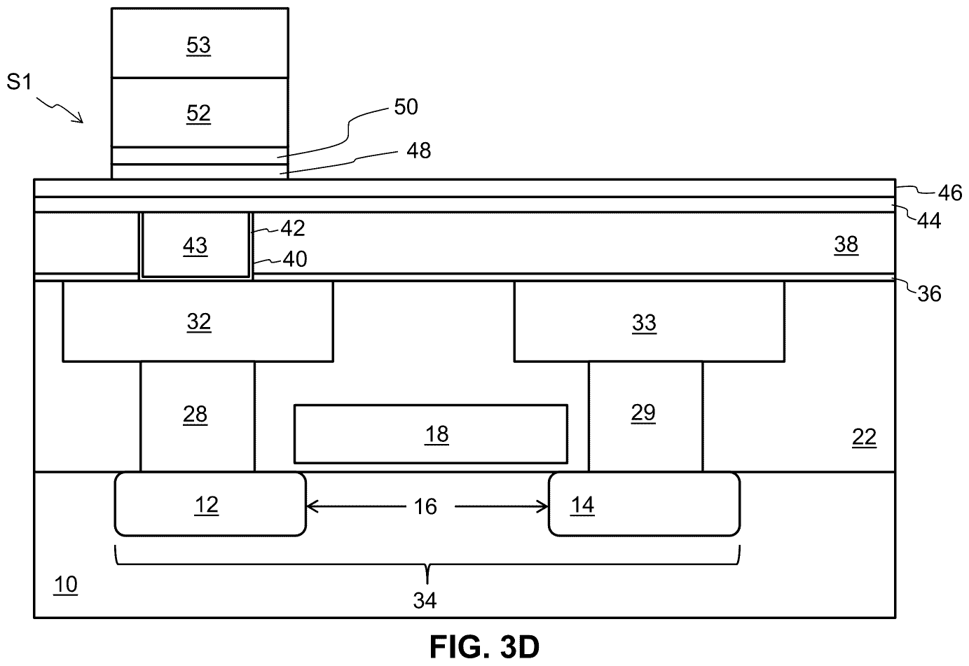

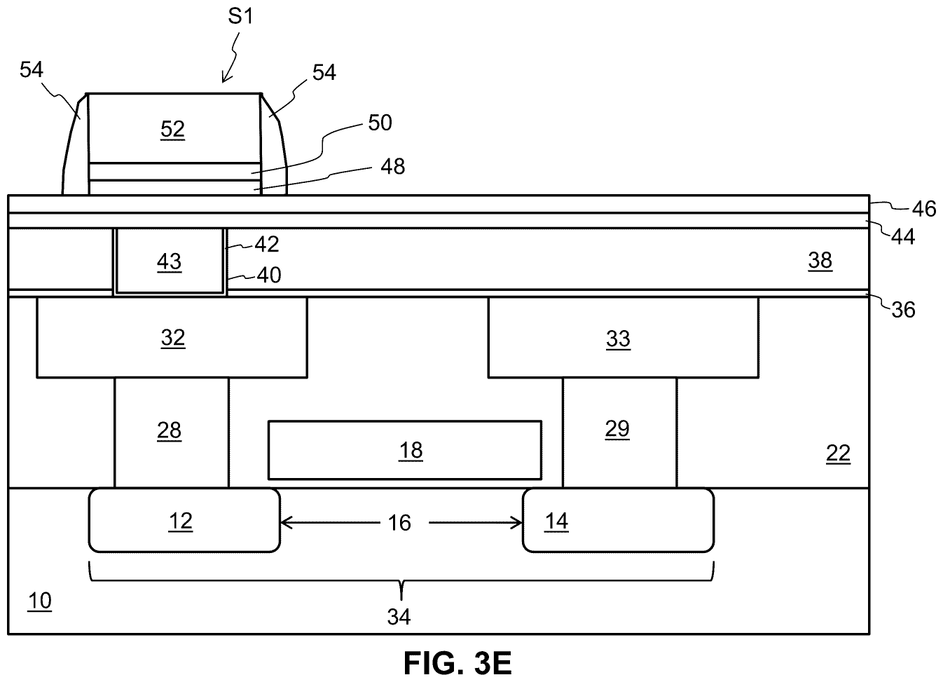

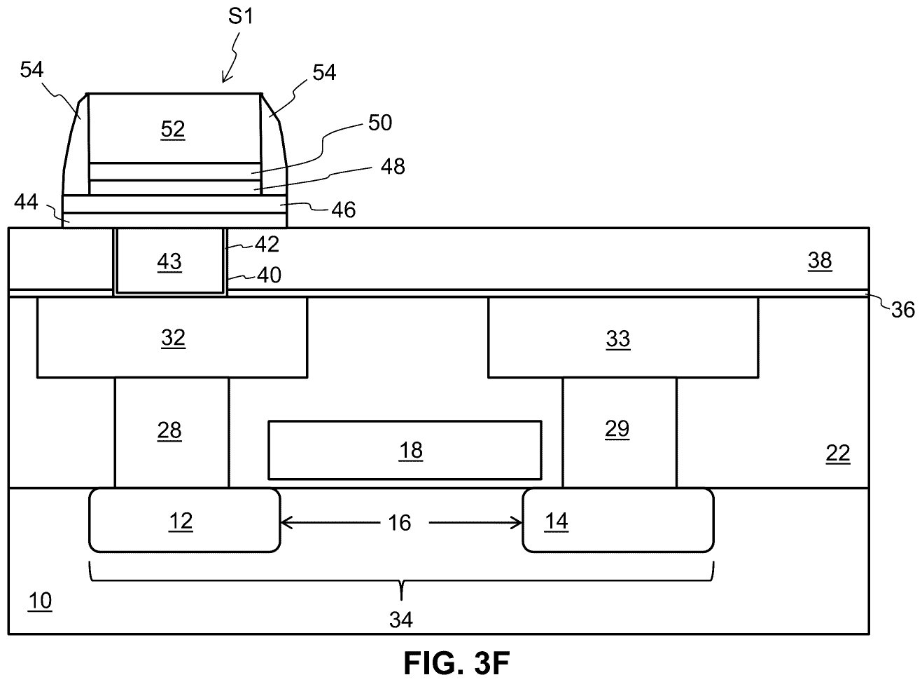

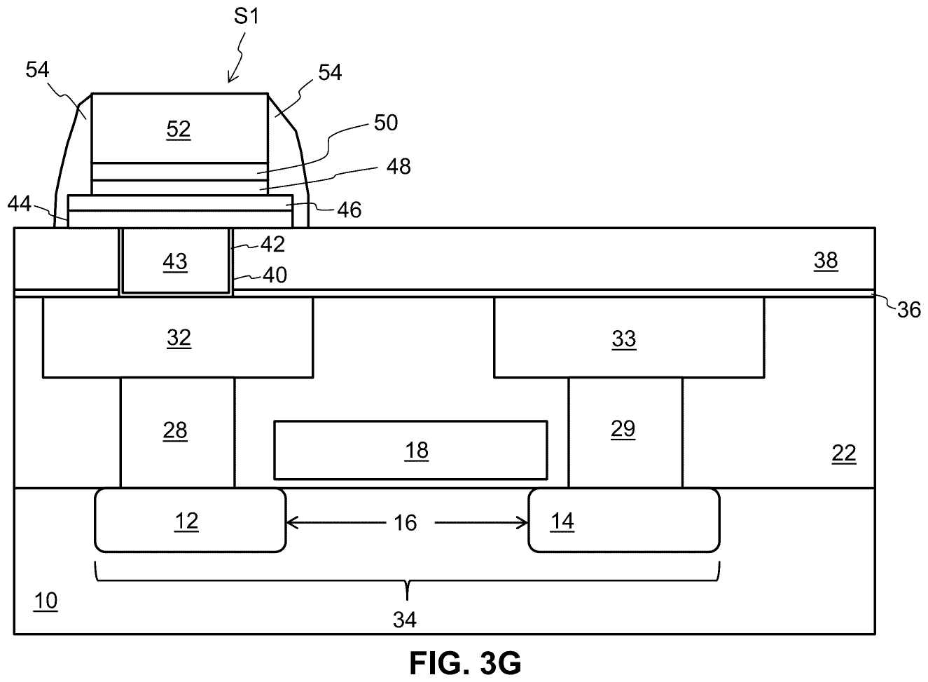

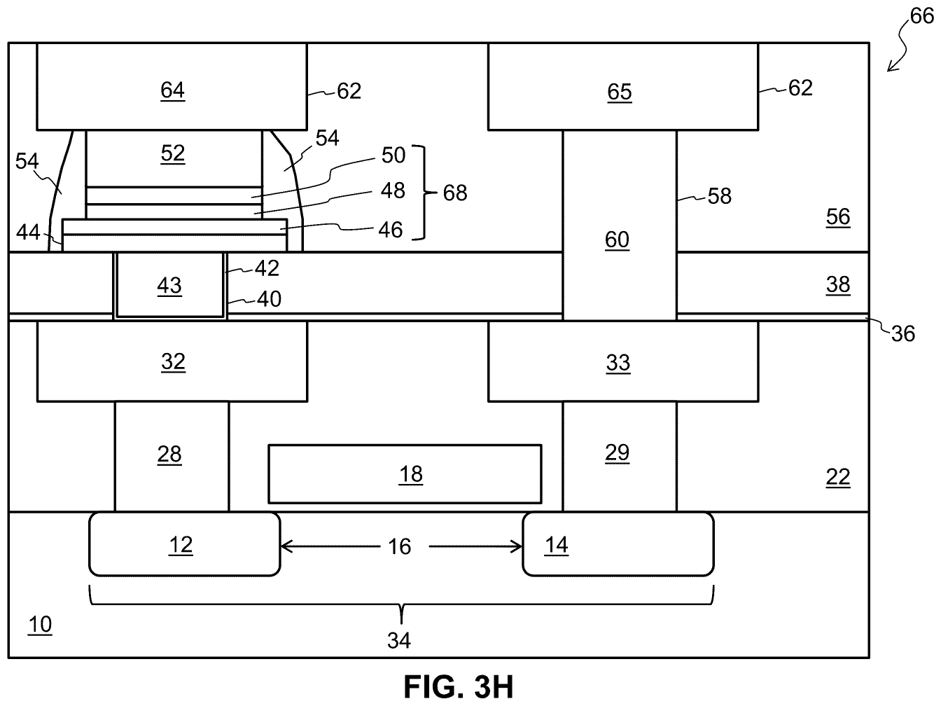

A method of forming a memory device with RRAM memory cells is shown in FIGS. 3A-3G, and starts by forming the structure shown in FIG. 3A. Specifically, a drain region 12 and source region 14 having a first conductivity type (e.g., n+) are formed in a semiconductor substrate 10 (e.g. silicon) having a second conductivity type (e.g., p+), by for example implantation, which define a channel region 16 in the semiconductor substrate 10 extending between the drain region 12 and source region 14. A conductive gate 18 (e.g., made of conductive material such as polysilicon or metal) is formed over and insulated from channel region 16 of the semiconductor substrate 10. Formation of the conductive gate can include formation of an oxide layer 20 (e.g., silicon oxide, silicon dioxide, hafnium oxide, and combinations thereof) which is an insulation material disposed between the semiconductor substrate 10 and the conductive gate 18, followed by a polysilicon or metal gate deposition on the oxide layer 20, followed by a photolithography and etch process (e.g. photoresist deposition, exposure and selective removal, followed by poly etch) that selectively removes the polysilicon layer except for that portion thereof that constitutes conductive gate 18. Insulation material 22 (e.g. oxide) is then formed over the semiconductor substrate 10. Contact holes 24 are formed in insulation material 22 by a photolithography and an etch process, that expose the drain region 12 and source region 14. The contact holes 24 can be lined with an optional barrier layer 26, such as TaN/Ta. A metal material is then deposited, such as tungsten or copper, followed by a chemical mechanical polish (CMP), to fill contact holes 24 with the metal material to form via contacts 28, 29 that are electrically connected to the exposed drain region 12 and source region 14, respectively. Additional insulation is deposited to raise insulation material 22 (e.g., by oxide deposition). The insulation material 22 is patterned to form contact holes 30 disposed over and exposing via contacts 28, 29. A layer of metal material is deposited on the structure (e.g., copper), followed by a CMP process, to fill the contact holes 30 with the metal material to form conductive contacts 32, 33 in electrical contact with via contacts 28, 29, respectively. The resulting structure is shown in FIG. 3A. The drain region 12, source region 14, the channel region 16 and the conductive gate 18 form a transistor 34 for selectively operating the RRAM cell being formed next.

An insulation layer 36 (e.g., SiN/SiCN) is formed on conductive contacts 32, 33 and insulation material 22. Insulation material 38 (e.g., oxide) is formed in insulation layer 36. The insulation material 38 and insulation layer 36 are patterned to form a contact hole 40 that exposes conductive contact 32. A metal barrier layer 42 (e.g. TaN/Ta) is formed on the structure, including in contact hole 40. A layer of metal material is deposited on the structure (e.g., copper or tungsten), followed by a CMP process, to fill the contact hole 40 with the metal material to form conductive contact 43 that is in electrical contact with conductive contact 32. The resulting structure is shown in FIG. 3B.

A conductive layer 44 (e.g., TaN) is formed on the structure. A lower electrode layer 46 is formed on the conductive layer 44. Lower electrode layer 46 can be made of a conductive material, such as TiN, TaN, HfN, TaAlN, Ti, Ta, Pt, Iridium, or Ruthenium. A resistive switching dielectric material layer 48 (also referred to herein as RSDM layer 48) is formed on the lower electrode layer 46. RSDM layer 48 can be a single layer of switching oxide such as a transition metal oxide (e.g., HfO₂, Al₂O₃, TaOₓ, TiOₓ, WOₓ, VOₓ, CuOₓ). RSDM layer 48 can also include multiple sublayers of different oxides and metals. Non-limiting examples of sublayers that can be included in RSDM layer 48 can include a sublayer of oxygen scavenger metal such as Ti or Ta on a sublayer of a transition metal oxide (e.g., HfO₂, Al₂O₃, TaOₓ, TiOₓ, WOₓ, VOₓ, CuOₓ), or a sublayer of HfO₂ and a sublayer of Al₂O₃, or a sublayer of HfO₂ and a sublayer of Hf and a sublayer of TaOₓ, or a sublayer of HfO₂ and a sublayer of Ti and a sublayer of TiOₓ. An upper electrode layer 50 is formed on RSDM layer 48. Upper electrode layer 50 can be made of a conductive material, such as TiN, TaN, HfN, TaAlN, Ti, Ta, Pt, Iridium, or Ruthenium. A conductive layer 52 (e.g., TaN) is formed on upper electrode layer 50. The resulting structure is shown in FIG. 3C.

The conductive layer 52 is patterned (i.e., covered with photoresist, which is partially removed through photolithography, where exposed portions of conductive layer 52 are selectively removed by for example an etch). For example, photoresist is formed on conductive layer 52, and then exposed and developed by a photolithography process whereby portions of the photoresist are selectively removed except for a block of the photoresist 53. One or more etches are then used to selectively remove exposed portions of conductive layer 52, upper electrode layer 50 and RSDM layer 48 (i.e., those portions not under, and therefore not protected from the etch(es) by, the block of the photoresist 53). This process leaves a stack structure S1 of a block of the conductive layer 52 disposed on a block of the upper electrode layer 50, which is disposed on a block of the RSDM layer 48, as shown in FIG. 3D.

After the block of photoresist 53 is removed, insulation spacers 54 are then formed on the sides of stack structure S1. Formation of spacers is well known, which includes forming a layer of material over the topology of a structure and performing an etch that removes the material from horizontal portions of the structure but leaves spacers of such material extending along vertical surfaces of the structure. Insulation spacers 54 can be formed of silicon nitride (referred to herein as nitride) by nitride deposition and etch. The resulting structure is shown in FIG. 3E, where the block of the RSDM layer 48 is under the block of the upper electrode layer, which is under the block of the conductive layer, and the insulation spacers 54 extend along the sidewalls of these three blocks.

An etch is then used to selectively remove the exposed portions of lower electrode layer 46 and conductive layer 44 (i.e. those portions of these layers not underneath the block of the conductive layer 52, the block of the upper electrode layer 50, the block of the RSDM layer 48, and insulation spacers 54). The stack structure S1 after this etch includes the block of the conductive layer 52, the block of the upper electrode layer 50, the block of the RSDM layer 48 (with side surfaces thereof abutting inner facing side surfaces of insulation spacers 54 that face each other), a block of the lower electrode layer 46 and a block of conductive layer 44 (with side surfaces thereof aligned with outer facing side surfaces of insulation spacers 54 that face away from each other), as shown in FIG. 3F. A deposition and etch is performed to thicken the insulation spacers 54 so that insulation spacers 54 extend along the side surfaces of block of the lower electrode layer 46 and the block of the conductive layer 44, as shown in FIG. 3G.

The structure is covered in insulation material 56 (e.g., oxide), which is planarized down to the block of the conductive layer 52. The insulation material 56 is patterned to form contact hole 58 down to and exposing conductive contact 33. A layer of metal material is deposited on the structure (e.g., copper), followed by a CMP process, to fill the contact hole 58 with the metal material to form via contact 60 in electrical contact with conductive contact 33. Additional insulation is deposited to raise insulation material 56 (e.g., by oxide deposition). The insulation material 56 is patterned to form contact holes 62 over the block of conductive layer 52 and the via contact 60. A layer of metal material is deposited on the structure (e.g., copper), followed by a CMP process, to fill the contact holes 62 with the metal material to form conductive contact 64 in electrical contact with the block of the conductive layer 52 and conductive contact 65 in electrical contact with via contact 60. The resulting structure is shown in FIG. 3H, which is a semiconductor device 66 having a RRAM cell 68 that includes the block of the upper electrode layer 50, which is on the block of the RSDM layer 48, which is on the block of the lower electrode layer 46.

The method of forming the semiconductor device has many advantages. For example, the RRAM cell formation can be implemented as part of the metal BEOL (Back End Of Line) portion of the process flow, which is typically the tail end of the process flow for making semiconductor devices where metal interconnects are formed throughout the semiconductor device to electrically connect the various components. Doing so can reduce the number of masking steps to form the RRAM cell 68 as well as the interconnections within the semiconductor device 66. Only a single patterning step is used to define the block of the lower electrode layer 46, the block of the RSDM layer 48 and the block of the upper electrode layer 50, even though the block of the lower electrode layer 46 has a first lateral dimension that is greater than a second lateral dimension of the block of the RSDM layer and the block of upper electrode layer 50. Metal re-deposition is therefore avoided along the sidewalls of the blocks of these layers that can short them together. Over-etching is also avoided on the sidewalls of the blocks of these layers which can damage the RSDM material, form rough sidewall surfaces, and degrade the cell performance. Insulation spacers 54 protect the sidewalls of the block of the upper electrode layer 50 and the block of the RSDM layer 48 after those blocks are formed, and the insulation spacers 54 are used as a self-aligned mask for etching the lower electrode layer 46 to form the block of the lower electrode layer 46 which has larger lateral dimensions than the blocks above it.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper formation of the semiconductor device described herein. Single layers of material could be formed as multiple layers of such or similar materials, and vice versa. For example, conductive layer 52 could be omitted, conductive layer 44 could be omitted, or insulation layer 36 could be omitted, or a combination thereof could be omitted. Lastly, the terms “forming” and “formed” as used herein shall include material deposition, material growth, or any other technique in providing the material as disclosed or claimed.

It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a semiconductor substrate” can include forming the element directly on the semiconductor substrate with no intermediate materials/elements there between, as well as forming the element indirectly on the semiconductor substrate with one or more intermediate materials/elements there between.

What is claimed is:

1. A method of forming a semiconductor device, comprising:
forming insulation material over a semiconductor substrate;
forming a first contact hole extending through the insulation material;
forming a first conductive contact in the first contact hole;
forming a lower electrode layer over the insulation material and electrically connected with the first conductive contact;
forming a resistive switching dielectric material layer directly on the lower electrode layer;
forming an upper electrode layer directly on the resistive switching dielectric material layer;
selectively removing portions of the upper electrode layer to form a block of the upper electrode layer;
selectively removing portions of the resistive switching dielectric material layer to form a block of the resistive switching dielectric material layer disposed under the block of the upper electrode layer;
forming insulation spacers on the lower electrode layer and extending along sidewalls of the block of the upper electrode layer and the block of the resistive switching dielectric material layer; and
selectively removing portions of the lower electrode layer to form a block of the lower electrode layer, wherein the block of the lower electrode layer is disposed under the insulation spacers and the block of the resistive switching dielectric material layer and the block of the upper electrode layer.

2. The method of claim 1, wherein the selectively removing portions of the upper electrode layer and the selectively removing portions of the resistive switching dielectric material layer comprise:
forming photoresist over the upper electrode layer and the resistive switching dielectric material layer;
exposing and developing the photoresist to remove portions of the photoresist to form a block of the photoresist; and
performing one or more etches to selectively remove portions of the upper electrode layer and portions of the resistive switching dielectric material layer, wherein the block of the upper electrode layer and the block of the resistive switching dielectric material layer are disposed under the block of the photoresist.

3. The method of claim 1, wherein:
the insulation spacers include inner facing side surfaces that face each other, and outer facing side surfaces that face away from each other;
the block of the upper electrode layer and the block of the resistive switching dielectric material layer include side surfaces that abut the inner facing side surfaces of the insulation spacers; and
the block of the lower electrode layer includes side surfaces aligned with the outer facing side surfaces of the insulation spacers.

4. The method of claim 1, wherein before the selectively removing portions of the upper electrode layer and the selectively removing portions of the resistive switching dielectric material layer, comprising:
forming a conductive layer on the upper electrode layer; and
selectively removing portions of the conductive layer to form a block of the conductive layer;
wherein after the selectively removing portions of the upper electrode layer to form a block of the upper electrode layer, the block of the conductive layer is disposed on the block of the upper electrode layer.

5. The method of claim 1, comprising:
forming a transistor on the semiconductor substrate; and
forming a second conductive contact that is electrically connected to the transistor and to the first conductive contact.

6. The method of claim 5, wherein the second conductive contact comprises a metal material.

7. The method of claim 5, wherein the second conductive contact comprises copper or tungsten.

8. The method of claim 5, comprising:
forming a conductive layer on the insulation material; and
selectively removing portions of the conductive layer to form a block of the conductive layer that is disposed between the block of the lower electrode layer and the first conductive contact.

9. The method of claim 8, wherein the conductive layer comprises TaN.

10. The method of claim 8, wherein the block of the conductive layer comprises sidewalls that are aligned with sidewalls of the block of the lower electrode layer.

11. The method of claim 1, comprising:
after the forming of the block of the lower electrode layer, thickening the insulation spacers such that the insulation spacers extend along sidewalls of the block of the lower electrode layer.

12. The method of claim 1, wherein the first conductive contact comprises a metal material.

13. The method of claim 1, wherein the first conductive contact comprises copper or tungsten.

14. The method of claim 1, wherein the first conductive contact comprises a layer of TaN and Ta.

15. The method of claim 1, wherein the lower electrode layer and the upper electrode layer each comprise TiN, TaN, HfN, TaAlN, Ti, Ta, Pt, Iridium, or Ruthenium.

16. The method of claim 1, wherein the resistive switching dielectric material layer comprises HfO2, Al2O3, TaOx, TiOx, WOx, VOx or CuOx.

17. The method of claim 1, wherein the resistive switching dielectric material layer comprises a sublayer of HfO₂ and a sublayer of Al₂O₃.

18. The method of claim 1, wherein the resistive switching dielectric material layer comprises a sublayer of HfO₂, a sublayer of Hf, and a sublayer of TaOx.

19. The method of claim 1, wherein the resistive switching dielectric material layer comprises a sublayer of HfO₂, a sublayer of Ti, and a sublayer of TiOx.
